(19) United States
(12) Patent Application Publication
(10) Pub. No.: US 2025/0228038 A1
(43) Pub. Date: Jul. 10, 2025

(54) Photovoltaic Module

(71) Applicant: Sun Terra Ltd., Nataf (IL)

(72) Inventors: Moshe Finarov, Rehovot (IL); Elie Meimoun, Jerusalem (IL)

(21) Appl. No.: 18/700,287

(22) PCT Filed: Jan. 14, 2022
(86) PCT No.: PCT/IL2022/050058

§ 371 Date: Apr. 11, 2024

(51) Int. Cl. H10F 77/70; H02S 20/10; H10F 77/30

(52) U.S. Cl. CPC H10F 77/707; H02S 20/10; H10F 77/311

(57) ABSTRACT

A PV module configured for vertical mounting, in which at least one cover glass has an external textured surface. The pattern of such texture is a plurality of triangular prisms. The height of the prisms is directed either parallelly or perpendicularly, or obliquely relative to the PV module's long side. The apparatus utilizes the sunlight at around noontime, mostly reflected from the glass at the grazing angles by redirecting the sunlight towards the PV cells inside the PV module. The sunlight harvesting is significantly higher than for PV modules with a smooth external surface. A polymer coating on the glass may also provide the texture pattern.

### TECHNOLOGY FIELD

The present disclosure relates to the field of photovoltaic (PV) modules and panels, particularly photovoltaic modules intended for vertical mounting.

### DISCUSSION OF RELATED ART

Photovoltaic (PV) modules are widely used in solar power installations—both roof-top and ground types. Usually, the photovoltaic panels' installations are rows of PV modules or panels either slightly tilted at an angle to the South with some distance between the rows or fully horizontal PV panels in dense arrangements. This type of installation is usually termed a North-South or N/S mounting or installation. The installation site latitude could require adjustments of the panel orientation and the tilt angle. Recently bifacial photovoltaic modules with high efficiency (>70%) have become available. These panels photovoltaic efficiency gain of 5% to 15% compared to monofacial (single side) PV modules depending on installation arrangement and the localized albedo.

Bifacial PV modules support a new type of installation of solar PV panels—vertical mounting (also termed East-West or E/W mounting). In the East-West photovoltaic panels installation, one side of the PV module collects sunlight before noon, and another side of the PV module collects the sunlight afternoon.

In a paper presented on 35th European Photovoltaic Solar Energy Conference and Exhibition (EU PVSEC 2018), Brussels, September 2018 titled PERFORMANCE ANALYSIS OF VERTICALLY MOUNTED BIFACIAL PV MODULES ON GREEN ROOF SYSTEM” by Thomas Baumann et al, reported that “according to simulations, vertically mounted bifacial modules can have a higher electrical energy yield than standard bifacial installations depending on the location and the installation conditions.”Muhammad Hussnain Riaz et al, in a paper titled “Module Technology for Agrivoltaics: Vertical Bifacial vs. Tilted Monofacial Farms”, published in arXiv: 1910.01076v2 [physics.app-ph] 23 Aug. 2020, concluded that “Remarkably, the vertical farm produces essentially the same energy output and photosynthetically active radiation (PAR) compared to traditional farms as long as the PV array density is reduced to half or lower relative to that for the standard ground mounted PV farms”

U.S. Patent Application Publication No. 2020/0153380 A1 to Heiko Hildebrandt, et al incorporated herein by reference in its entirety, teaches “a PV system in which a plularity of bifacial PV modules can be mounted in a vertical arrangement and which satisfies the specific requirements of bifacial modules.”

Traditionally mounted photovoltaic panels generate the maximal electrical power at the noon hours. There is a significant dip in electrical power generation in the vertical photovoltaic panels mounting around noontime. The sunlight at the noon does not penetrate through the cover glass to the PV module's silicon PV cells.

### DEFINITIONS

As used in the current disclosure, the term “bifaciality” defines the PV panel rear side efficiency ratio to the front side efficiency, measured under standard test conditions.

Albedo s a non-dimensional, unitless quantity that indicates how well a Earth surface reflects solar radiation. Albedo varies between 0 and 1. Albedo commonly refers to the “whiteness” of a surface, with 0 meaning black and 1 meaning white.

As used in the current disclosure term “grazing angle” is defined as the Angle of Incidence” (AOI) close to 90°, for example, between 80° to 90°.

### SUMMARY

The present disclosure describes a PV module design, in which the cover glass surface of at least one side of the PV module is textured. The texture supports redirection of the sunlight rays impinging the PV module at grazing angles instead of being reflected from the glass surface away from the PV module towards the photovoltaic cells inside the PV module.

In one example, the present disclosure provides a PV module design, in which a thin transparent film coats the glass cover of at least one side. The transparent film has a surface textured such that it redirects the sunlight rays impinging the PV module at grazing angles instead of being reflected from the film surface inside the PV module.

These, and additional, and/or other aspects and/or advantages of the present disclosure are set forth in the detailed description which follows; possibly inferable from the detailed description; and/or learnable by practice of the present invention.

### LISTING OF DRAWINGS AND THEIR BRIEF DESCRIPTION

For a better understanding of embodiments of the method and apparatus and to show how the same may be carried into effect, reference is made to the accompanying drawings in, which like referral numerals, designate identical or similar elements throughout the document.

FIG. 1 is a typical glass reflection as a function of the angle of ‘incidence’

FIG. 2 is an example of a cover glass surface texture of a PV module;

FIG. 3 is a schematic illustration of possible orientations of the cover glass texture pattern; and

FIG. 4 is an example of a PV module glass cover coated with a textured film.

For simplicity and clarity of explanation, elements shown in the figures have not necessarily been drawn to scale. For example, the dimensions of some of the elements may be exaggerated relative to other elements for clarity.

### DESCRIPTION

The traditional photovoltaic panel installations occupy a relatively large surface. The vertical photovoltaic panel installations generating a similal electric power occupy a significantly smaller surface and space. The availability of free available for conventional PV panels installations surfaces becomes limited.

The drop of electrical power generation around noon in vertically installed PV panels reduces the power throughput of vertically installed PV panels.

The following description, presents various aspects of the present apparatus and method. For the purposes of explanation, specific configurations and details are set forth in order to provide a thorough understanding of the present disclosure. However, it will also be apparent to one skilled in the art that the present apparatuus and method could be practiced without the specific details presented herein. In order not to obscure the present disclosure, some known available features have been omitted or simplified.

The present disclosure provides an efficient method of enhancing the efficiency of the PV modules and potentially decreasing their cost in terms of Dollar per Watt-peak ($/Wp).

The disclosure supports the use of PV modules in other types of mounting and configurations than the vertical mount. Other applications may comprise horizontal mounts with or without a tilt to the South or the North and tracking systems with one or two tracking axes.

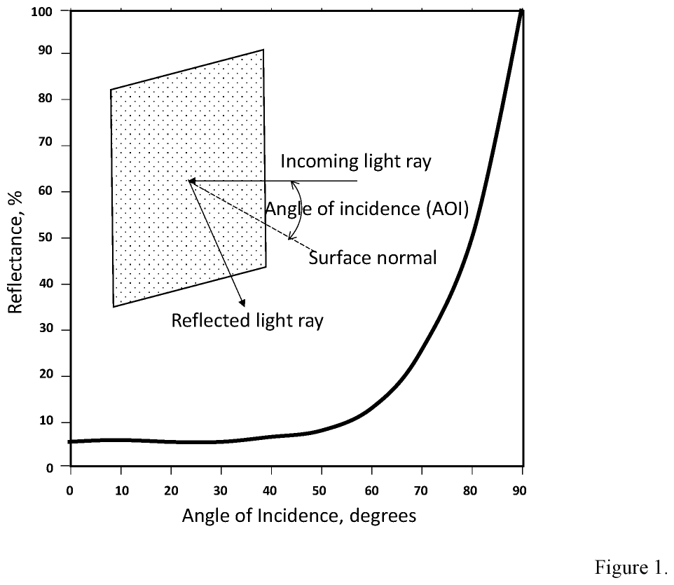

FIG. 1 shows a light reflectance from a standard flat glass surface at different angles of incidence (AOI). It is known in the art that at AOI greater than 60° (60 degrees) the reflectance of the incident light is rapidly increasing with AOI. At the grazing angles of incidence (greater than about) 80° most of the light is reflected. It means that the sunlight practically does not enter the cover glass at the grazing angles and thus does not reach the PV cells located within the PV module behind the cover glass. This problem is especially significant for vertically mounted PV modules because the grazing angles around noon when the sunlight irradiance is the highest throughout the daytime. Therefore, the solution for reducing the PV module reflection and increasing the light transmitted through the glass cover into the PV at the grazing angles could increase the PV modules' efficiency, especially for vertical mounts.

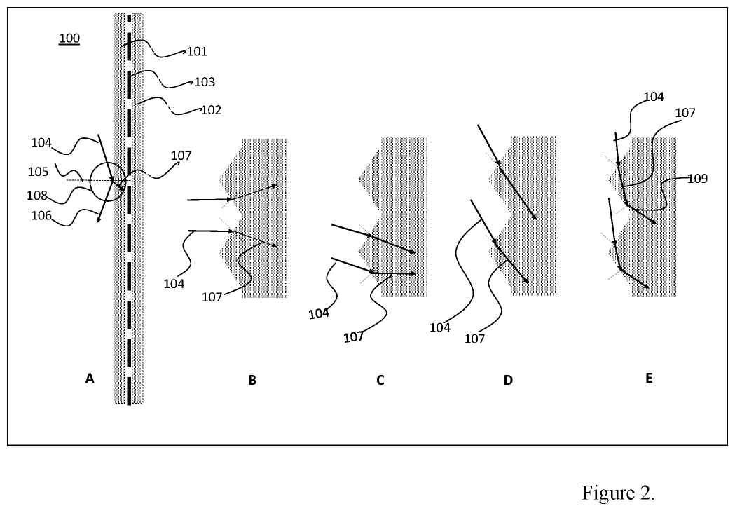

FIG. 2 is an example of a cover glass surface texture profile of a PV module. The figure shows that providing a specific texture on the sunlight receiving surface of at least one cover glass of PV module 100 in a vertical mount it is possible to direct the incident sunlight into the cover glass and subsequently onto the PV module. It is noted that the plane of this module is located in a plane with its normal 105 parallel to the East-West direction.

View A of FIG.2 is a cross-section of a PV module 100 mounted in a vertical orientation. The module includes a frontside glass cover 101, backside plate 102, which may be made of glass or other transparent material, and multiple silicon PV cells 103 located between them. The PV cells may be of different types: unifacial and bifacial, made of crystalline silicon or other semiconductor material or semiconductor thin films. In the case of bifacial PV cells, the backside plate is also made of glass, and all further description of the surface texture related to the frontside glass cover also relates to the backside glass cover.

Views B, C, D, and E of FIG. 2 show magnified details of the texture of the surface of the front side glass. In all the views the sunlight ray vectors of incident light 104 and refracted light 107, accordingly, schematically show the sunlight rays at different daytime: View B at the time of sunrise (the sunlight rays coming from the East), View C at the early morning time, View D at the late morning time, E—about the noontime. In the case of the bifacial PV module backside 102 is also made of textured glass. At the afternoon, the incident sunlight rays are substantially symmetrical to the sunlight rays incident on the front-side glass 101 before noon.

The pattern of the glass surface texture is a plurality of prisms with a triangular base 306 and height 307 oriented along one of the glass cover sides—either length 304 or width 305. The angles of the base triangle could be different. For simplicity of description, presented here is an equilateral triangle; however, it may also be an isosceles triangle or a triangle with all different angles.

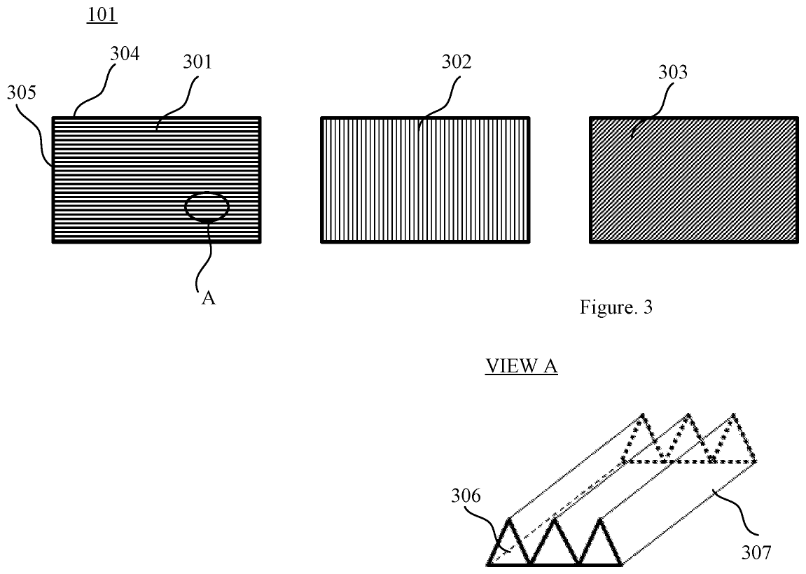

FIG. 3 shows possible orientations of the texture pattern and View A shows the a small section of the texture prism structure in a magnified scale. FIG. 3 shows that in the PV module cover glass 101 the direction of the prism height may be parallel 301 or perpendicular 302 or oblique 303 to the module perimetric sides, in particular, to the long side 304 of the module. The optimal texture pattern design defined by prism orientation and triangle' angles, which provide maximal sunlight harvesting gain, may differ at different places on Earth (defined by the local latitude).

In FIGS. 2B, 2C, and 2D, the incoming rays 104 are refracted at one of the prisms faces, and the refracted rays 107 propagate towards PV cells located behind the cover glass. FIG. 2E shows a sunlight ray tracing in case of grazing incidence at around noon. The incident ray 104 is refracted at one of the prism surfaces, and the refracted rays 107 are fully reflected from the opposite triangle face due to the effect of total internal reflection (TIR) so the reflected ray 109 is redirected towards the PV cells inside the PV module. FIGS. 2B, 2C, 2D, 2E are examples of sunlight ray paths, representing the general behavior of the sunlight. Other sunlight ray paths, including Fresnel reflection, total internal reflection (TIR), and refraction on one, two or more optical surfaces are possible.

The physical dimensions of the triangular prism basis may be different and depend on the used glass cover thickness and a manufacturing method applied for glass texturing. PV modules usually have cover glasses of 2-3 mm thick, and may have a pattern of prisms in the range of 10 microns to 1 mm. The direction of height of the prism is one of a group of heights that could be a height parallel, perpendicular, or oblique to a long side of the module.

Some manufacturing limitations may alter the perfect triangular shape and, for example, create a radius of curvature instead of the sharp edges of a perfect triangle. For the purpose of the current document, the triangles with rounded angles are still considered as triangles.

Optical design simulations show that a textured cover glass e.g., with an equilateral triangular prism shape for vertical PV module yields about 8% sunlight harvesting gain as compared to a flat cover glass. The harvesting gain figure is valid for parallel and perpendicular directions of the prism height relative to the ground. A similar textured glass could also be used for regular horizontal or South-tilted PV panels.

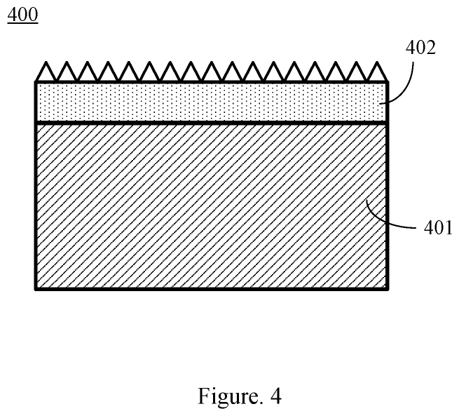

FIG. 4 is an example of a PV module glass cover coated with a textured film. Instead of texturing the glass plate, it is possible to cover a standard glass plate with a thin film coating material with a similar texture pattern, including a plurality of the triangular prisms. As shown in FIG. 4, a uniform textured coating 402 covers a light-receiving surface of glass cover 401. A coating material 402 attached to the glass plate 401, is a uniform textured light-receiving surface with embossed a plurality of prisms with a triangular base. The uniform textured coating material 402 is a polymer film suitable for patterning by embossing. The polymer film is a hydrophobic anti-soiling film.

The transparent thin textured film 402 could be attached to the glass surface using any known method. It could be easier to manufacture a textured film, for example, by a-known method of pattern embossing. Since such film is usually thin, e.g., with thickness of tens to hundreds of microns, the size of the equvilateral triangular base could be from few microns to tens of microns.

The listed below film materials are sufficiently transparent for sunlight, and stable to meet the changing surrounding conditions: temperature, air humidity, dust, etc. The materials have a refractive index close to the one of the cover glass and reduce parasitic reflections at the interface. The materials could be selected from a non-limiting list of materials including a group of polymer materials, which can be patterned by the embossing process. Such materils could be: polyethylene, polypropylene, fully aromatic polyester, other copolymer polyester, polymethyl methacrylate, other copolymer acrylate, polycarbonate, polyamide, polyether sulfone, polyether ketone, polyether imide, aromatic polyimide, alicyclic polyimide, fluorinated polyimide, cellulose acetate, cellulose nitrate, aromatic polyamide, polyvinyl chloride, polyphenol, polyacrylate, polyphenylene sulfide, polyphenylene oxide, polystyrene. It is possible to use for such textured film a hydrophobic anti-soiling coating produced via a chemical process compatible with glass manufacturing (like it is described in the article Hydrophobic anti-soiling coating for solar modules” by Emiliano Bellini in PV-magazine of Nov. 15, 2021). Such coating posses both anti-reflection properties and resistance to contaminations. The materials posess reduced cleaning requirements, improve the amount of harvested sunlight and decrease maintenance expenses.

While the apparatus and method have been described with respect to a limited number of examples, these should not be construed as limitations on the scope of the apparatus and method, but rather as exemplifications of some of the preferred embodiments. Other possible variations, modifications, and applications are also within the scope of the disclosure. Accordingly, the scope of the disclosure should not be limited by what has been described, but by the appended claims and their legal equivalents.

1. A photovoltaic A photovoltaic module, comprising:
at least one photovoltaic element covered by a glass plate; and wherein a light-receiving surface of the glass plate is a uniformly textured surface.

2. The photovoltaic module of claim 1, wherein the uniformly textured surface is a plurality of prisms having a triangular base.

3. The photovoltaic module of claim 2, wherein a direction of height of the prism is one of a group of heights consisting of a height parallel, perpendicular, or oblique to a long side of the module.

4. The photovoltaic module of claim 2, wherein the triangle base is equilateral.

5. The photovoltaic module of claim 2, wherein size of the triangle base is tens of microns to one millimeter.

6. The photovoltaic module of claim 1, wherein the photovoltaic module is configured for installation vertically relative to the ground.

7. The photovoltaic module of claim 6, wherein the module is configured to be oriented along South-North direction.

8. A photovoltaic module, comprising:
at least one photovoltaic element; at least a glass cover plate with a uniform textured coating of a light-receiving surface; and
wherein the uniform textured light-receiving surface is a plurality of prisms with a triangular base.

9. The photovoltaic module of claim 8, wherein the uniform textured coating material is a polymer film suitable for patterning by embossing.

10. The photovoltaic module of claim 8, wherein the uniform textured coating material is a hydrophobic anti-soiling film.

11. The photovoltaic module of claim 8, wherein a direction of height of a prism is one of a group of heights consisting of a height parallel, perpendicular, or oblique to a long side of the module.

12. The photovoltaic module of claim 8, wherein the triangle base is equilateral.

13. The photovoltaic module of claim 8, wherein the triangular base size is several microns to several tens of microns.

14. The photovoltaic module of claim 8, wherein the module is configured for installation vertically relative to the ground.

15. The photovoltaic module of claim 14, wherein the module is configured to be oriented along South-North direction.

16. A photovoltaic module comprising:
a frontside glass cover;
a backside glass plate; and
a multiplicity of silicon PV cells located between the frontside glass cover and the backside glass plate;
wherein light-receiving surfaces of the frontside cover and backside glass plate include a uniform texture configured to direct the sunlight ray vectors of incident light and refracted light at different daytime towards the PV cells.

17. The photovoltaic module of claim 16, wherein the glass surface texture is a plurality of prisms with a triangular base and height oriented along one of the glass cover sides.

18. The photovoltaic module of claim 16, wherein the glass surface texture is a uniform textured coating embossed on a polymeric material attached to the glass surface.
